(19) United States
(12) Patent Application Publication
(10) Pub. No.: US 2021/0357061 A1
(43) Pub. Date: Nov. 18, 2021

(54) FLEXIBLE IMAGE DISPLAY DEVICE AND OPTICAL LAMINATE FOR USE IN SAME

(71) Applicant: Nitto Denko Corporation, Ibaraki-shi, Osaka (JP)

(72) Inventors: Yasutaka Ishihara, Ibaraki-shi (JP); Takanobu Yano, Ibaraki-shi (JP); Sho Takarada, Ibaraki-shi (JP)

(73) Assignee: Nitto Denko Corporation, Ibaraki-shi, Osaka (JP)

(21) Appl. No.: 17/285,352

(22) PCT Filed: Oct. 2, 2020
(86) PCT No.: PCT/JP2020/037604

§ 371 Date: Apr. 14, 2021

(30) Foreign Application Priority Data
Oct. 9, 2019 (JP) 2019-186256
Sep. 24, 2020 (JP) 2020-159579

(51) Int. Cl. G06F 3/041; B32B 27/08

(52) U.S. Cl. CPC G06F 3/0412; B32B 27/08; B32B 2457/208; B32B 2307/40; B32B 2307/536; G06F 2203/04102; B32B 2307/51

(57) ABSTRACT

A flexible image display device includes a window member, a first member, a first laminate or a first touch-sensor-equipped panel member, and a plurality layers of tacky members. The first laminate is a laminate of a second member and a member 3A (including a panel member). When the first laminate is included, one of the first and second members is an optical film, and the other is an optical film or a touch sensor. The plurality layers of tacky members at least include three layers each disposed between the members. When the first touch-sensor-equipped panel member is included, the first member is an optical film, and the plurality layers of tacky members at least include two layers each disposed between the members. E0×T0≤0.32 (E0: elastic modulus (GPa) of the window member, T0: thickness (mm) of the window member).

### TECHNICAL FIELD

The present invention relates to a flexible image display device including a plurality layers of tacky members and to an optical laminate.

### BACKGROUND ART

A flexible image display device includes, for example, a panel member including a display panel, and an optical laminate disposed in front of the panel member. The optical laminate includes, for example, a window member and an optical film, and in some cases, further includes a touch sensor. There is provided an adhesive layer or a tacky layer between members included in the optical laminate and between the panel member and the optical laminate.

For example, Patent Literature 1 proposes a foldable display device including a display panel, a polarizing member provided on the display panel, a window provided on the polarizing member, a first adhesive member provided between the display panel and the polarizing member, and a second adhesive member provided between the polarizing member and the window. Patent Literature 1 discloses that the foldable display device can include a touch sensing unit. Patent Literature 1 further discloses a foldable display device provided with a window WD, a touch sensing unit TSU, a polarizing member POL, and a display panel DP. A first adhesive member AD1 is disposed between the window WD and the touch sensing unit TSU, a fourth adhesive member AD4 is disposed between the touch sensing unit TSU and the polarizing member POL, and a second adhesive member AD2 is disposed between the polarizing member POL and the display panel DP.

### CITATION LIST

### Patent Literature

[PTL 1] Japanese Laid-Open Patent Publication No. 2017-126061 (claim 1, [0132], [0138], and FIG. 7B)

### SUMMARY OF INVENTION

### Technical Problem

In a flexible image display device, the window member side thereof comes to a surface (on the viewing side). Therefore, the surface on the window member side is required to have a high pencil hardness. However, even though a high pencil hardness can be achieved by the window member alone, the pencil hardness may be considerably reduced in some cases when the window member is laminated to another member via a tacky member.

### Solution to Problem

One aspect of the present invention relates to a flexible image display device, including: a window member; a first member laminated to the window member; a first laminate or a first touch-sensor-equipped panel member laminated to the window member via the first member; and a plurality layers of tacky members, wherein the first laminate is a laminate of a second member and a member 3A, the second member laminated via the first member to the window member, the member 3A laminated via the first member and the second member to the window member; when the flexible image display device includes the first laminate, one of the first member and the second member is an optical film, and the other is an optical film or a touch sensor, the member 3A includes at least a panel member, and the plurality layers of tacky members at least include three layers disposed respectively between the window member and the first member, between the first member and the second member, and between the second member and the member 3A; when the flexible image display device includes the first touch-sensor-equipped panel member, the first member is an optical film, and the plurality layers of tacky members at least include two layers disposed respectively between the window member and the first member, and between the first member and the first touch-sensor-equipped panel member; the window member has an elastic modulus (GPa) denoted by E0 and a thickness (mm) denoted by T0, satisfying E0×T0≤0.32; and a thickness of each of the plurality layers of tacky members satisfies a condition of 18 nm or less.

Another aspect of the present invention relates to an optical laminate for use in the above flexible image display device, the optical laminate including: a window member; a first member laminated to the window member; a second laminate or a first separator laminated to the window member via the first member; and a plurality layers of tacky members, wherein the second laminate is a laminate of a second member and a member 3B, the second member laminated via the first member to the window member, the member 3B laminated via the first member and the second member to the window member; when the optical laminate includes the second laminate, one of the first member and the second member is an optical film, and the other is an optical film or a touch sensor, the member 3B includes at least a second separator, and the plurality layers of tacky members at least include three layers disposed respectively between the window member and the first member, between the first member and the second member, and between the second member and the member 3B; when the optical laminate includes the first separator, the first member is an optical film, and the plurality layers of tacky members at least include two layers disposed respectively between the window member and the first member, and between the first member and the first separator; the window member has an elastic modulus (GPa) denoted by E0 and a thickness (mm) denoted by T0, satisfying E0×T0≤0.32; and a thickness of each of the plurality layers of tacky members satisfies a condition of 18 μm or less.

### Advantageous Effects of Invention

A high pencil hardness can be ensured at the surface on the window member side of a flexible image display device and an optical laminate for use in the flexible image display device.

### BRIEF DESCRIPTION OF DRAWINGS

FIG. 1 A schematic cross-sectional view of a flexible image display device according to a first embodiment of the present invention.

FIG. 2 A schematic cross-sectional view of a flexible image display device according to a second embodiment of the present invention.

FIG. 3 A schematic cross-sectional view of a flexible image display device according to a third embodiment of the present invention.

### DESCRIPTION OF EMBODIMENTS

A flexible image display device according to the present invention includes a window member, a first member laminated to the window member, a first laminate or a first touch-sensor-equipped panel member laminated to the window member via the first member, and a plurality layers of tacky members. The first laminate is a laminate of a second member and a member 3A, the second member laminated via the first member to the window member, the member 3A laminated via the first member and the second member to the window member.

When the flexible image display device includes the first laminate, one of the first member and the second member is an optical film, and the other is an optical film or a touch sensor. The member 3A includes at least a panel member. In this case, the plurality layers of tacky members at least include three layers disposed respectively between the window member and the first member, between the first member and the second member, and between the second member and the member 3A.

When the flexible image display device includes the first touch-sensor-equipped panel member, the first member is an optical film. In this case, the plurality layers of tacky members at least include two layers disposed respectively between the window member and the first member and between the first member and the first touch-sensor-equipped panel member.

Furthermore, the present invention also encompasses an optical laminate for use in the above flexible image display device. The optical laminate includes a window member, a first member laminated to the window member, a second laminate or a first separator laminated to the window member via the first member, and a plurality layers of tacky members. The second laminate is a laminate of a second member and a member 3B, the second member laminated via the first member to the window member, the member 3B laminated via the first member and the second member to the window member.

When the optical laminate includes the second laminate, one of the first member and the second member is an optical film, and the other is an optical film or a touch sensor. The member 3B includes at least a second separator. The plurality layers of tacky members at least include three layers disposed respectively between the window member and the first member, between the first member and the second member, and between the second member and the member 3B.

When the optical laminate includes the first separator, the first member is an optical film. In this case, the plurality layers of tacky members at least include two layers disposed respectively between the window member and the first member and between the first member and the first separator.

The optical laminate is used in a flexible image display device, with the separator (specifically, the first separator or the second separator included in the member 3B) removed therefrom. The aforementioned flexible image display device includes the optical laminate from which the separator has been removed, with the window member disposed on the viewing side.

In the flexible image display device and the optical laminate mentioned above, the window member has an elastic modulus (GPa) denoted by E0 and a thickness (mm) denoted by T0, satisfying E0×T0≤0.32. The value obtained by multiplying the elastic modulus by the thickness (=E0×T0) indicates the degree of resilience (or hardness) of the window member. Here, the unit of E0×T0 is kN/mm.

The flexible image display device, whose surface on the window member side is on the viewing side, is used with the surface exposed. Therefore, the surface on the window member side is require to have high scratch resistance. The scratch resistance of the surface on the window member side can be evaluated by, for example, a pencil hardness test. It was found, however, that even though a high pencil hardness can be obtained by the window member alone, the pencil hardness may be reduced considerably when the window member is laminated to other members (e.g., an optical film and a touch sensor) via a tacky member and formed into a flexible image display device. The tacky member, unlike an adhesive member that is cured to bond one member to another, holds its high viscosity even in a state where one member is laminated to another via the tacky member. Therefore, with the tacky member present in the flexible image display device, the stress caused when the surface on the window member side is pressed can be relaxed by the tacky member. At this time, however, the tacky member deforms, making it difficult for the surface to resume its original shape. Consequently, the scratch resistance is reduced. The reduction in scratch resistance becomes severe when the optical laminate includes a plurality layers of tacky members. On the other hand, in the case of an adhesive member in a cured state, the stress relaxation as observed in the case of a tacky member is unlikely to occur, causing almost no reduction in scratch resistance. In the flexible image display device, since a high flexibility is required for its components, the influence by the tacky member with high viscosity on the pencil hardness is considered to be more noticeable.

In the flexible image display device and the optical laminate according to the present invention, when E0×T0≤0.32, the thickness of each of the plurality layers of tacky members is set so as to satisfy a condition of 18 μm or less. By setting as above, despite the presence of at least three layers or at least two layers of tacky members in the flexible image display device and the optical laminate, the deformation of the tacky member that occurs when the surface on the window member side is pressed can be reduced, and a high scratch resistance (specifically, high pencil hardness) at the surface on the window member side can be ensured. Moreover, by using at least three layers or at least two layers of tacky members, a high flexibility of the optical laminate can also be ensured.

Note that the adhesive member is a cured adhesive, and does not have fluidity. On the other hand, the tacky member is a non-curable adhesive, and has fluidity.

The flexible image display device according to the present invention has a pencil hardness of the window member side of higher than F. In the flexible image display device according to the present invention, a high pencil hardness of H or higher, 2H or higher, or 4H or higher can be ensured on the window member side.

The pencil hardness as used herein refers to a scratch hardness (pencil method) specified in JIS K 5600-5-4: 1999. The pencil hardness can be measured in accordance with JIS K 5600-5-4: 1999, under a load of 750 g at 25° C.

The hardness of each of the members, including the window member, in the flexible image display device or the optical laminate can be adjusted by, for example, adjusting the material, the layer structure and/or the thickness of each member.

### (Tacky Member)

The optical laminate or the flexible image display device includes a plurality layers of tacky members. Specifically, when the flexible image display device (or optical laminate) includes the first laminate (or second laminate), the flexible image display device (or optical laminate) at least includes three layers of tacky members disposed respectively between the window member and the first member, between the first member and the second member, and between the second member and the member 3A (or member 3B). When the flexible image display device (or optical laminate) includes the first touch-sensor-equipped panel member (or first separator), the plurality layers of tacky members at least include two layers of tacky members disposed respectively between the window member and the first member and between the first member and the first touch-sensor-equipped panel member (or first separator). The plurality layers of tacky members may include a tacky member other than these three or two layers of tacky members disposed between adjacent members. The tacky member other than the above three or two layers of tacky members is disposed within each member (specifically, within at least one member selected from the group consisting of the window member, the first member, the second member, the member 3A (or member 3B), and the first touch-sensor-equipped panel member). The tacky member is usually in the form of a layer. The number of the tacky members within each member is not specifically limited, and there may be no layer, or there may be one layer, or two or more layers. As described above, the tacky members (i.e., the plurality layers of tacky members) included in the flexible image display device or the optical laminate encompass both the tacky member between adjacent members, and the tacky member(s) included within each member.

The number of the tacky members included in the flexible image display device or the optical laminate may be, for example, eight layers or less, seven or six layers or less, and five or four layers or less.

The thickness of each of the layers of tacky members included in the flexible image display device or the optical laminate is 18 μm or less. The thickness may be 16 μm or less, and may be 15 μm or less. In the present invention, when the value obtained by multiplying the elastic modulus E0 (GPa) of the window member and the thickness T0 (mm) of the window member satisfies E0×T0≤0.32, the thickness of each of the layers of tacky members is set to be in the range above. By setting as above, regardless of what kind of material the tacky member is constituted of, a high pencil hardness can be ensured on the window member side of the flexible image display device.

In view of ensuring a high bendability in the flexible image display device, the thickness of each of the layers of tacky members is preferably 3 μm or more, more preferably 5 μm or more. The thickness may be 8 μm or more or 10 μm or more, and may be set to 13 μm or more.

In the flexible image display device, in some cases, a decoration layer is provided so as to be in contact with one of the plurality layers of tacky members, between a surface on the first member side of the window member and the touch sensor or the touch-sensor-equipped panel member (specifically, the first or second touch-sensor-equipped panel member). When the thickness of the tacky member is small at a portion where the decoration layer is provided, the tacky member can hardly absorb the level difference formed by the decoration layer. In view of the ease of absorbing the level difference due to the decoration layer, the thickness of the tacky member to be in contact with the decoration layer may set to 10 μm or more.

In view of the ease of absorbing the level difference due to the decoration layer, the thickness of the tacky member to be in contact with the decoration layer may be set to be 1.5 times as large as the thickness of the decoration layer. The thickness may be set to 2 times or more or 2.5 times or more, and further to 3 times or more as large as the thickness of the decoration layer.

The aforementioned upper limit and lower limit values of the thickness of the layer of tacky member may be combined in any combination.

The thickness of the tacky member is determined by cutting out a cross section of the flexible image display device or the optical laminate and based on a SEM (scanning electron microscope) image of the cross section. The thickness of the tacky member is determined as an average of the thicknesses measured at any plural points (e.g., 5 points) in the area where the decoration layer is not present, on the above SEM image of the cross section.

The storage modulus at 25° C. of each of the tacky members is usually 10 MPa or less, and may be 3 MPa or less or 2 MPa or less, and may be 1.5 MPa or less. The storage modulus at 25° C. of each tacky member is preferably 1 MPa or less, which may be 0.3 MPa or less or 0.2 MPa or less, and may be 0.15 MPa or less or 0.1 MPa or less. When the storage modulus of the tacky member is in such a range, a high adhesiveness can be ensured, and, unlike in the case of an adhesive member in a cured state, the stress caused by pressing can be readily relaxed, and the pencil hardness is unlikely to be reduced. According to the present invention, even in the case where the flexible image display device includes a plurality of such tacky members that can easily relax the stress caused by pressing, a high pencil hardness can be ensured by controlling the thickness of each of the layers of tacky members. The storage modulus at 25° C. of each tacky member may be 0.001 MPa or more, and may be 0.005 MPa or more.

The aforementioned upper limit and lower limit values of the storage modulus of the tacky member may be combined in any combination.

On the other hand, the storage modulus at 25° C. of the adhesive member is greater than 10 MPa, and may be 100 MPa or more, and usually about 1 GPa. As used herein, the adhesive member means an adhesive member having such a storage modulus.

The tacky member is differentiated from the adhesive member by the storage modulus.

The storage modulus of the tacky member can be measured in accordance with JIS K 7244-1:1998. Specifically, first, a shaped object having a thickness of about 1.5 mm is produced using the tacky member. The shaped object is punched into a disk shape with a diameter of 7.9 mm, to produce a test piece. The test piece is sandwiched between parallel plates, and viscoelasticity measurement is performed using a dynamic viscoelasticity measurement device (e.g., “Advanced Rheometric Expansion System (ARES)” manufactured by Rheometric Scientific LTD.) under the following conditions, to determine a storage modulus at 25° C. Note that the storage modulus of the adhesive member can also be determined similarly to that of the tacky member.

### (Measurement Conditions)

Deformation mode: torsion

Measurement frequency: 1 Hz

Measurement temperature: −40° C. to +150° C.

Rising temperature: 5° C./min

From the viewpoint of ensuring high visibility of the panel member, the total light transmittance of each tacky member is preferably 85% or more, and more preferably 90% or more.

The total light transmittance of the tacky member can be measured in accordance with JIS K 7136K: 2000. For the measurement, a test piece obtained by disposing the tacky member on alkali-free glass (thickness: 0.8 to 1.0 mm, total light transmittance: 92%) to a thickness of about 1.5 mm.

The tacky member is formed of a tackiness agent. The type of the tackiness agent is not particularly limited, and examples thereof include an acrylic tackiness agent, a rubber-containing tackiness agent, a silicone-containing tackiness agent, a urethane-series tackiness agent, a vinyl alkyl ether-series tackiness agent, a polyvinyl pyrrolidone-series tackiness agent, a polyacrylamide-series tackiness agent, and a cellulose-series tackiness agent. The tackiness agent may include, but is not limited to, for example, a base polymer, a crosslinking agent, an additive (e.g., a tackifier, a coupling agent, a polymerization inhibitor, a crosslinking retarder, a catalyst, a plasticizer, a softening agent, a filler, a colorant, metal powder, an ultraviolet absorber, a light stabilizer, an antioxidant, a degradation inhibitor, a surfactant, an antistatic agent, a surface lubricant, a leveling material, a corrosion inhibitor, particles of an inorganic or organic material (metal compound particles (metal oxide particles, etc.), resin particles, etc.).

A tackiness agent that can provide the storage modulus as above can be advantageously used as the tackiness agent. In this case, the effect produced by controlling the thickness of the tacky members can be obtained remarkably. Of the plurality layers of tacky members, at least two layers of tacky members may be constituted of the same tackiness agent, or all tacky members may be constituted of different tackiness agents.

The tacky member can be formed, for example, by applying a tackiness agent constituting each tacky member, or transferring the tackiness agent shaped in a sheet form, to one of the members between which the each tacky member is to be sandwiched. Then, the other of the members between which the each tacky member is to be sandwiched is laminated to the tacky member. Each tacky member is thus disposed between the members. In the case where the tacky member is included within each member, too, the tacky member can be disposed within the member in a way similarly to disposing between the members. For example, by disposing a tacky member utilizing application or transfer of a tackiness agent as described above, onto one of the layers (or laminates) which constitute the each member and between which the tacky member is to be sandwiched, and then, attaching the other layer (or laminate) to the tacky member, the tacky member can be disposed within each member.

### (Window Member)

The window member is disposed at the outermost on the viewing side of the flexible image display device or the optical laminate, in order to prevent breakage of the optical film, the touch sensor, the touch sensor-equipped panel member, and the panel member.

When the value obtained by multiplying the elastic modulus E0 and the thickness T0 of the window member satisfies E0×T0≤0.32, the properties of the plurality of layers of tacky members included in the flexible image display device or the optical laminate have a significant influence on the pencil hardness at the surface on the window member side. In the present invention, by controlling the thickness of each of the layers of tacky members, a high pencil hardness can be ensured at the surface on the window member side.

The window member usually includes a window film. The flexible image display device or the optical laminate applied thereto is required to have high flexibility (high pliability, etc.), high transparency (a high total light transmittance and a low haze, etc.), and a high degree of hardness. The material of the window film is not particularly limited as long as it satisfies these physical properties.

Examples of the window film include a transparent resin film. Examples of the resin that constitutes the transparent resin film include at least one selected from a polyimide-based resin, a polyamide-based resin, a polyester-based resin, a cellulose-series resin, an acetate-series resin, a styrene-series resin, a sulfone-series resin, an epoxy-series resin, a polyolefin-based resin, a polyether ether ketone-based resin, a sulfide-series resin, a vinyl alcohol-series resin, a urethane-series resin, an acrylic resin, and a polycarbonate-based resin. However, the resin that constitutes the transparent resin film is not limited thereto.

The thickness of the window film is, for example, 20 μm or more and 500 μm or less, and may be 30 μm or more and 200 μm or less. When the window film has such a thickness, both high strength and high bendability can be easily achieved simultaneously.

As used herein, “being transparent” when used for a member (shaped body) other than the tacky member or a material other than the tackiness agent means that a test piece of that member or material has a total light transmittance of 80% or more. For the measurement of the total light transmittance, a test piece formed of a transparent material or member and having a thickness of about 1.5 mm is used. The total light transmittance can be measured similarly to that of the tacky member.

The window member may include a hard coat layer. From the viewpoint of easily achieving high effect of preventing breakage of the window film, the hard coat layer is preferably provided at least on the side opposite the side facing the first member of the window member. Specifically, the hard coat layer is preferably provided at least on a surface on the side opposite the side facing the first member (i.e., on the viewing side) of the window film.

The thickness of the hard coat layer is, for example, 1 μm or more and 100 μm or less, and may be 1 μm or more and 50 μm or less. When the window member includes a plurality of hard coat layers, the thickness of each hard coat layer may be set within such a range.

The hard coat layer is formed, for example, by applying a curable coating agent to the surface of an underlying layer (e.g., a window film), and curing the applied coating agent.

As the coating agent, a coating agent for use in an optical film can be used. Examples of the coating agent include, but are not are limited to, an acrylic coating agent, a melamine-series coating agent, a urethane-series coating agent, an epoxy-series coating agent, a silicone-containing coating agent, and an inorganic substance-containing coating agent.

The coating agent may contain an additive. Examples of the additive include, but are not limited to, a silane coupling agent, a colorant, a dye, powder or particles (a pigment, an inorganic or organic filler, particles of an inorganic or organic material, etc.), a surfactant, a plasticizer, an antistatic agent, a surface lubricant, a leveling agent, an antioxidant, a light stabilizer, an ultraviolet absorber, a polymerization inhibitor, and an anti-fouling material.

The window member may include another layer (hereinafter referred to as a layer A) as needed. Examples of the layer A include an antireflection layer, an antiglare layer, an anti-fouling layer, an anti-sticking layer, a hue adjustment layer, an antistatic layer, an easily adhesive layer, a layer for preventing precipitation of ion or an oligomer or the like, a shock-absorbing layer, and an anti-splinter layer. The window member may include one layer A, or a plurality of layers A. The layer A is provided, for example, on the surface side or on first member side of another layer or a laminate (e.g., a window film) constituting the window member. The layer A may be directly formed using a coating or the like on another layer or a laminate constituting the window film, or may be laminated thereto via an adhesive member or a tacky member.

The thickness T0 of the window member is, for example, 0.02 mm or more and 0.6 mm or less, and may be 0.03 mm or more and 0.3 mm or less.

The thickness T0 of the window member is determined by cutting out a cross section of the flexible image display device or the optical laminate and based on a SEM image of the cross section. The thickness T0 is determined as an average of the thicknesses measured at any plural points (e.g., 5 points) on the above SEM image of the cross section.

Herein, the thickness of each member constituting the optical laminate or the flexible image display device can be determined similarly to the thickness T0 of the window member.

The elastic modulus E0 of the window member is, for example, 0.53 GPa or more and 16 GPa or less, and may be 1 GPa or more and 15 GPa or less, 1 GPa or more and 11 GPa or less (or 10 GPa or less), or 3 GPa or more and 8 GPa or less.

The elastic modulus E0 (GPa) of the window member is an average value (arithmetic mean value) obtained by preparing three measurement samples of the window member, measuring the elastic modulus of each of the samples by a tensile test, and averaging the measured values. The tensile test can be performed under the following conditions, using the following device.

Tensile tester: Autograph AG-1S, manufactured by SHIMADZU CORPORATION

Control: stroke

Gauge length: 100 mm

Tensile speed: 50 mm/min

Elastic modulus calculation range: 10 N/mm² to 20 N/mm²

Note that the samples for measuring the elastic modulus are produced as follows. First, the window member is measured for its elastic moduli in the longitudinal and lateral directions. Then, the window member is cut into a strip shape such that the length in the direction in which the elastic modulus is higher than that in the other direction is 150 mm and the length in the direction in which the elastic modulus is lower than that in the other direction is 10 mm, and thus, the sample is produced. To cut the window member, a multi-purpose test piece cutter manufactured by DUMBBELL CO., LTD. is used, for example.

E0×T0 (kN/mm) is 0.32 or less, and may be 0.3 or less. E0×T0 is, for example, 0.01 or more, and may be 0.02 or more, 0.05 or more, 0.1 or more, or 0.2 or more. These upper limit and lower limit values may be combined in any combination.

### (First Member and Second Member)

In the flexible image display device and the optical laminate, the first member is laminated to the window member. When the flexible image display device (or the optical laminate) includes the first laminate (or the second laminate), the second member is laminated to the window member via the first member. The tacky member is interposed between the window member and the first member and between the first member and the second member. When the flexible image display device (or the optical laminate) includes the first laminate (or the second laminate), one of the first member and the second member is an optical film, and the other is an optical film or a touch sensor. The flexible image display device (or the optical laminate) may include the member 3A (or the member 3B), in which one of the first and second members may be an optical film, and the other may be a touch sensor. When the flexible image display device includes the first touch sensor-equipped panel member, and when the optical laminate includes the first separator, the first member may be an optical film. When the member 3A includes the second touch sensor-equipped panel member, the first member and the second member may be an optical film.

The first member and the second member are included in the flexible image display device and, therefore, have moderate strength and flexibility. When the elastic moduli (GPa) of the first member and the second member are denoted by E1 and E2, respectively, and the thicknesses (mm) of the first member and the second member are denoted by T1 and T2, respectively, the first member and the second member preferably satisfy the following. When the value obtained by multiplying the elastic modulus by the thickness is within the range below in each member, the effect produced by controlling the thickness of each layer of tacky member as above can be more easily obtained.

0.01≤E1×T1≤0.35 (first member)

0.01≤E2×T2≤0.35 (second member)

Here, the units of E1×T1 and E2×T2 are both kN/mm.

### (Optical Film)

The optical film is a film for imparting optical functions. The optical film is usually a laminate including at least one layer having an optical function. Examples of the optical film include those used in the field of image display devices and the like. Each of the first member and the second member may be an optical film, or may be one layer or a laminate of two or more layers constituting an optical film.

Examples of the layer having an optical function include a layer having optical anisotropy (e.g., an optical anisotropic film). Examples of the layer having optical anisotropy include, but are not limited to, a polarizer, a retardation layer, a viewing angle expansion film, a viewing angle limiting (anti-peek) film, a brightness enhancement film, and an optical compensation film. The laminate of two or more layers may include two or more layers selected from these layers having optical anisotropy. In the laminate of two or more layers, all layers having optical anisotropy may have different functions, or at least two layers may have the same function. For example, the laminate may include a polarizer and a retardation layer, or may include two retardation layers having different compositions.

The optical film may include at least one layer having an optical function and a base material layer that holds (or a protective layer that protects) this layer. For example, a polarizing plate at least includes a film polarizer, and may be constituted of the polarizer and a protective film that protects the polarizer.

The flexible image display device and the optical laminate preferably include, as the optical film, at least a polarizer or a polarizing plate.

The polarizer is not particularly limited, and any polarizer used in the field of image display devices and the like can be used. Examples of the polarizer include a film obtained by causing a hydrophilic polymer film to adsorb a dichroic substance, and uniaxially stretching the film, and a polyene-based oriented film. Examples of the hydrophilic polymer that constitutes the hydrophilic polymer film include a polyvinyl alcohol-based resin (also including a partially formalized polyvinyl alcohol-based resin), and a partially saponified product of an ethylene-vinyl acetate copolymer. Examples of the dichroic substance include iodine and a dichroic dye. Examples of the material that constitutes the polyene-based oriented film include a dehydrated product of a polyvinyl alcohol-based resin and a dehydrochlorinated product of a polyvinyl chloride-based resin.

As the polarizer, a thin polarizer having a thickness of 10 μm or less may be used. Examples of the thin polarizer include polarizers described in Japanese Laid-Open Patent Publication No. 51-069644, Japanese Laid-Open Patent Publication No. 2000-338329, WO 2010/100917, Japanese Patent No. 4691205, and Japanese Patent No. 4751481. The thin polarizer is obtained, for example, by a production method including the steps of stretching a polyvinyl alcohol-based resin layer and a resin base material layer in a laminated state, and dyeing the layers using a dichroic material.

The protective film may be, for example, a polymer film that is excellent in transparency, mechanical strength, thermal stability, moisture barrier properties, and optical isotropy. The protective film contains, as a polymer material having such properties, for example, at least one selected from the group consisting of a cellulose-series resin, a polyolefin-based resin (also including a cyclic polyolefin-based resin), an acrylic resin, an imide-series resin (also including a phenyl maleimide-series resin), a polyamide-based resin, a polycarbonate-based resin, a polyester-based resin (also including a polyarylate-based resin), an acetate-series resin, a polyether sulfone-based resin, a polyvinyl chloride-based resin, a polyvinylidene chloride-based resin, a polystyrene-based resin, a polyvinyl alcohol-based resin, a sulfide-series resin (e.g., a polyphenylene sulfide-based resin), a polyether ether ketone-based resin, an epoxy-series resin, and a urethane-series resin. However, the resin that constitutes the protective film is not limited to these polymer materials.

The optical film may include one layer of protective film, or two or more layers of protective films. The protective film may be disposed on one surface or both surfaces of a layer having an optical function (e.g., a polarizer). The optical film may include two or more layers, each layer having an optical function and including a protective film disposed on one surface thereof. When the optical film includes two or more layers of protective films (e.g., when the protective film is disposed on both surfaces of the polarizer), all protective films may have different compositions, or at least two layers of protective films may have the same composition.

The optical film may include, in addition to the polarizer or the polarizing plate, another film for imparting optical functions (hereinafter, layer B) other than the polarizer or the polarizing plate. Examples thereof used as the layer B include those utilized in the field of image display devices and the like. The layer B may be, for example, an optical anisotropic film. The layer B may be selected from the layers having optical anisotropy as mentioned above other than the polarizer or the polarizing plate. Specifically, the layer B is, for example, a retardation layer, a viewing angle expansion film, a viewing angle limiting (anti-peek) film, a brightness enhancement film, and an optical compensation film. The optical film may include such a layer B singly, or two or more. The layer B, however, is not limited to these.

The layer B may be laminated to the polarizing plate with or without the protective film interposed therebetween. When the polarizing plate has no protective film, the layer B serves as the protective film, too.

The thickness of the optical film is, for example, 5 μm or more and 500 μm or less, and may be 10 μm or more and 100 μm or less.

The thickness of the polarizing plate is, for example, 200 μm or less. In view of ensuring its high bendability, the thickness of the polarizing plate is preferably 100 μm or less, more preferably 80 μm or less or 70 μm or less. The thickness of the polarizing plate is, for example, 10 μm or more.

The thickness of the layer B is, for example, 0.1 μm or more and 100 μm or less. When the polarizing plate has no protective film (i.e., when the layer B serves as the protective film), it is preferable to adjust the thickness of the layer B such that a laminate of the layer B and the polarizing plate have a thickness within the range described for the thickness of the polarizing plate.

The layer constituting the optical film may be directly laminated to an adjacent layer, using a coating or the like. Alternatively, the layer constituting the optical film may be laminated via the adhesive member or the tacky member to an adjacent layer. For example, the layer B may be laminated via the adhesive member or the tacky member to the polarizing plate. When the optical film includes two or more layers B adjacent to each other, the adjacent layers B may be laminated to each other, either via the adhesive member or via the tacky member.

(Touch Sensor)

As the touch sensor, for example, a touch sensor used in field of image display devices and the like is used. Examples of the touch sensor include, but are not limited to, a resistive film touch sensor, a capacitive touch sensor, an optical touch sensor, and an ultrasonic touch sensor. When the optical film is present between the touch sensor and the window member in the flexible image display device and the optical laminate, high sensitivity can be easily achieved by using a capacitive touch sensor.

A capacitive touch sensor usually includes a transparent conductive layer. Examples of such a touch sensor include a laminate of a transparent conductive layer and a transparent base material. Examples of the transparent base material include a transparent film.

Although not by way of limitation, a conductive metal oxide, a metal nanowire, or the like is used for the transparent conductive layer. Examples of the metal oxide include indium oxide containing tin oxide (indium tin oxide: ITO), and tin oxide containing antimony. The transparent conductive layer may be a conductive pattern formed of a metal oxide or a metal. Examples of the form of the conductive pattern include, but are not limited to, a stripe form, a square form, and a grid form.

The surface resistance value of the transparent conductive layer is, for example, 0.1Ω/□ or more and 1000Ω/□ or less, and may be 0.5Ω/□ or more and 500Ω/□ or less.

The thickness of the transparent conductive layer is, for example, 0.005 μm or more and 10 μm or less, and may be 0.01 μm or more and 3 μm or less.

As the transparent film, a transparent resin film is used, for example. Examples of the resin that constitutes the transparent resin film include a polyester-based resin (also including a polyarylate-based resin), an acetate-series resin, a polyether sulfone-based resin, a polycarbonate-based resin, a polyamide-based resin, a polyimide-based resin, a polyolefin-based resin, an acrylic resin, a polyvinyl chloride-based resin, a polyvinylidene chloride-based resin, a polystyrene-based resin, a polyvinyl alcohol-based resin, a sulfide-series resin (e.g., a polyphenylene sulfide-based resin), a polyether ether ketone-based resin, a cellulose-series resin, an epoxy-series resin, and a urethane-series resin. The transparent resin film may include one kind, or two or more kinds of these resins. Among these resins, a polyester-based resin, a polyimide-based resin, and a polyether sulfone-based resin are preferable. However, the resin that constitutes the transparent resin film is not limited to these resins.

From the viewpoint of increasing the adhesion between the transparent conductive layer and the transparent base material, a surface-treated transparent base material may be used. As the surface treatment, a known surface treatment can be adopted. If necessary, prior to lamination of the transparent conductive layer, the transparent base material may be subjected to, for example, dust removal or cleaning treatment (such as washing treatment using a solvent, ultrasonic waves, or the like).

The touch sensor may include a layer (hereinafter referred to as a layer C) other than the transparent conductive layer and the transparent base material as needed. For example, an undercoat layer or a layer for preventing precipitation of an oligomer may be provided as the layer C, between the transparent conductive layer and the transparent base material. Alternatively, the layer C may be laminated to at least one surface of each of the transparent conductive layer and the transparent base material. Examples of the layer C include functional layers having a desired function (e.g., the aforementioned film for imparting optical functions (an optical anisotropic film, etc.), the aforementioned layer having an optical function)), and a decorated base film. The decorated base film is, for example, laminated to a surface of the transparent conductive layer. However, the layer C is not limited to these layers. The layer C may be laminated to the transparent conductive layer or the transparent base material via the adhesive member or the tacky member as needed.

The overall thickness of the touch sensor is, for example, 5 μm or more and 250 μm or less, and may be 10 μm or more and 200 μm or less.

### (Third Member)

In the flexible image display device and the optical laminate, the third member is laminated to the window member via the first member and the second member. The tacky member is interposed between the first member and the second member. The third member of the flexible image display device is referred to as a member 3A. The member 3A includes at least a panel member. The third member of the optical laminate is referred to as a member 3B. The member 3B includes at least a separator (second separator). The optical laminate is included, with the separator removed therefrom, in the flexible image display device. The member 3B includes neither the panel member nor the touch sensor-equipped panel member. The member 3A and the member 3B may be each in the form of a laminate. The member 3A and the member 3B may each include the adhesive member or the tacky member.

The member 3A includes at least a panel member. The member 3A may be, for example, a laminate of a panel member and a protective member that protects the panel member. When the member 3A includes a protective member, the protective member is usually laminated on the side opposite the side facing the second member of the panel member. In other words, the protective member is provided on the side opposite the viewing side of the panel member. It is to be noted, however, that these are mere examples, and the member 3A is not limited thereto. When the member 3A is a laminate, the adjacent layers (or members, e.g., the panel member and the protective member) constituting the laminate may be laminated via the adhesive member or the tacky member.

When the elastic modulus (GPa) of the member 3A is denoted by E3, and the thickness (mm) of the member 3A is denoted by T3, the member 3A preferably satisfies the following equation.

0.01≤E3×T3≤0.35.

When the value obtained by multiplying the elastic modulus by the thickness of the member 3A is within the range above, the effect produced by controlling the thickness of each tacky member as above can be more easily obtained. Here, the unit of E3×T3 is kN/mm.

The member 3B in the optical laminate includes at least a separator. The member 3B may include a separator only. The member 3B is laminated to the second member, with the separator brought into contact with the tacky member disposed on the side opposite the side facing the first member of the second member. After the separator is removed from the optical laminate, the exposed tacky member is attached to the member 3A (specifically, the panel member or a laminate including the panel member), and thus a flexible image display device is formed.

(Panel Member)

The panel member includes at least an image display panel, for example. A sealing member (a thin-film sealing layer or the like) may be disposed on the viewing side of the image display panel. The sealing member is usually directly disposed on a surface of the image display panel on the viewing side.

As the image display panel, a known image display panel is used. Examples of the image display panel include an organic electroluminescence (EL) panel.

(Protective Member)

Examples of the protective member include a sheet or film (or substrate) that holds or protects the panel member. The protective member may be any member having a suitable strength for holding the panel member and protecting the panel member, and a suitable flexibility that does not prevent bending of the flexible image display device. Examples of the protective member include a resin sheet. The material of the resin sheet is not particularly limited, and can be selected as appropriate according to, for example, the type of the image display panel.

(Touch Sensor-Equipped Panel Member)

The touch sensor-equipped panel member (specifically, each of a first touch sensor-equipped panel member, and a second touch sensor-equipped panel member included in the member 3A) is a panel member integrated with a touch sensor. Such a touch sensor-equipped panel member encompasses, for example, a configuration in which a capacitive touch sensor including a metal mesh electrode is formed on a thin-film sealing layer of an organic light emitting diode (OLED). As to the touch sensor, reference may be made to the above-described description.

The panel member includes at least an image display panel, for example. A sealing member (a thin-film sealing layer or the like) may be disposed on the viewing side of the image display panel. The sealing member is usually directly disposed on a surface of the image display panel on the viewing side.

As the image display panel, a known image display panel is used. Examples of the image display panel include an organic electroluminescence (EL) panel.

The touch sensor-equipped panel member may include a protective member. Examples of the protective member include a sheet or film (or substrate) that holds or protects the panel member. The protective member may be any member having a suitable strength for holding the panel member and protecting the panel member, and a suitable flexibility that does not prevent bending of the flexible image display device. Examples of the protective member include a resin sheet. The material of the resin sheet is not particularly limited, and can be selected as appropriate according to, for example, the type of the image display panel.

When the elastic modulus (GPa) of the touch sensor-equipped panel member is denoted by Ep, and the thickness (mm) of the touch sensor-equipped panel member is denoted by Tp, the touch sensor-equipped panel member preferably satisfies the following equation

0.01≤Ep×Tp≤0.35.

When the value obtained by multiplying the elastic modulus by the thickness of the touch sensor-equipped panel member is within the range above, the effect produced by controlling the thickness of each tacky member as above can be more easily obtained. Here, the unit of Ep×Tp is kN/mm.

(Separator)

As the separator (specifically, each of the first separator and the second separator included in the member 3B), a release sheet including a base material sheet and a release agent disposed on at least one surface of the base material sheet is used, for example. The separator is disposed in a state in which the release agent is in contact with the tacky member. Specifically, the first separator is disposed in contact with the tacky member disposed on the side opposite the side facing the window member of the first member. The second separator is disposed in contact with the tacky member disposed on the side opposite the side facing the first member of the second member.

The base material sheet may be any base material sheet which retains the configuration of the optical laminate, excluding the first separate or the member 3B, and has suitable strength and flexibility and on which a layer of the release agent can be easily formed. As the base material sheet, a resin film, paper, or a laminate thereof is used. The material of the base material sheet is determined according to the type of the release agent, the configuration of the optical laminate, and the like. As the resin film, a polyester film (a polyethylene terephthalate film or the like), a polyolefin film (a polypropylene film or the like) may be used, for example. The thickness of the base material sheet is also not particularly limited, and can be selected taking the desired releasability into account. As the release agent, a known release agent can be used, and it is preferable to select a release agent that reduces the residual amount of the tacky member in the separator. For example, a silicone-containing release agent or a fluorine-containing release agent may be used.

(Decoration Layer)

The decoration layer is provided, for example, so as to be in contact with one of the layers of tacky members, between the window member and the touch sensor or the touch sensor-equipped panel member (specifically, the first touch-sensor-equipped panel member or the second touch-sensor-equipped panel member). For example, the decoration layer may be provided on a surface on the first member side of the window member, or a surface on the first laminate side or on the first touch-sensor-equipped panel member side (or the first separator side) of the first member, or, when the second member is an optical film, on a surface on the member 3A side (or the member 3B side) of the second member. When a tacky member is included in at least one of the first member and the second member, the decoration layer may be disposed so as to be in contact with the tacky member. In order to prevent the lead wire of a driving element or a touch sensor from being seen from the outside, the decoration layer is usually provided in a frame-shaped pattern at a portion in the vicinity of the outer edge of a display portion in which an image is displayed. However, the shape of the decoration layer is not limited to a frame shape, and may be any shape that can conceal the lead wire and the like.

In addition to not reflecting the light from the viewing side, the decoration layer is required to block the light from the side opposite to the viewing side. Such a decoration layer can be formed, for example, by an ink layer, a metal thin film, or a thin film containing metal fine particles. A thin film containing metal fine particles contains, for example, metal fine particles and a binder resin. The decoration layer may have a monolayer structure, or may have a laminated structure. The decoration layer having a laminated structure may be, for example, a laminate of at least two selected from an ink layer, a metal thin film, and a thin film containing metal fine particles. This laminate also includes a laminate including two or more ink layers having different compositions, two or more metal thin films having different compositions, or two or more thin films containing metal fine particles having different compositions.

The thickness of the decoration layer is, for example, 10 μm or less, and may be 8 μm or less or 5 μm or less. When the decoration layer has a thickness in the above range, the high bending durability of the flexible image display device and the optical laminate tends to be ensured. In view of more effectively concealing the lead wire, the thickness of the decoration layer is preferably 10 nm or more, and more preferably 30 nm or more or 50 nm or more. These upper limit and lower limit values may be combined in any combination.

The decoration layer may be formed by, for example, applying a coating agent containing constituent components of the decoration layer, to a surface of a member or layer (excluding the sticky member) to be in contact with the decoration layer. For example, the decoration layer may be formed by applying a coating agent containing constituent components of the decoration layer, to a surface on the first member side of the window member, or a surface on the first laminate side or on the first touch sensor-equipped panel member side (or the first separator side) of the first member, or when the second member is the optical film, to a surface on the member 3A side (or the member 3B side) of the second member. The decoration layer may be formed by depositing the constituent components by a gas phase method on a surface of a member or layer (excluding the sticky member) to be in contact with the decoration layer. For example, the decoration layer may be formed by depositing the constituent components by a gas phase method, on a surface on the first member side of the window member, or on a surface on the first laminate side or the first touch sensor-equipped panel member side (or the first separator side) of the first member, or when the second member is the optical film, on a surface on the member 3A side (or the member 3B side) of the second member. Especially in the case of a metal thin film, a decoration layer having a small thickness can be easily formed by utilizing a gas phase method. Examples of the gas phase method include sputtering, vacuum vapor deposition, chemical vapor deposition (CVD), and electron-beam vapor deposition. When a decoration layer is formed in the manner as above on a surface of the layer or laminate constituting the first member or the second member, the decoration layer can be formed within each member.

On a surface of a member or layer (excluding the tacky member) to be applied with a coating agent, prior to the application, a primer layer may be disposed beforehand. For example, when the decoration layer is provided on a surface on the first member side of the window member, a primer layer may be disposed between the decoration layer and the surface on the first member side of the window member. When the decoration layer is provided on a surface on the first laminate side or on the first touch sensor-equipped panel member side (or the first separator side) of the first member, a primer layer may be disposed between the decoration layer and the surface on the first laminate side or on the first touch sensor-equipped panel member side (or the first separator side) of the first member. The primer layer includes at least one selected from the group consisting of, for example, a metal compound (a metal oxide, a metal nitride, a metal carbide, a metal sulfide, etc.), and a resin material. The primer layer is preferably transparent.

In view of allowing the tacky member to easily absorb the level difference due to the decoration layer, as well as suppressing the optical influence by the presence of the primer layer, the primer layer preferably has a small thickness. The thickness of the primer layer is, for example, 500 nm or less, and preferably 100 nm or less, or 30 nm or less.

The flexible image display device and the optical laminate are fabricated by, for example, laminating component members one after another, with a tacky member disposed between the members (and if necessary, between adjacent layers constituting each of the members). The order of lamination is not particularly limited.

For example, the window member and the first member may be laminated, with a tacky member interposed between these members, and then, the first member and the second member may be laminated, with a tacky member interposed between these members. The first member and the second member may be laminated, with a tacky member interposed between these members, and then, the first member and the window member may be laminated, with a tacky member interposed between these members. Each of the tacky members is preferably attached beforehand to one of the members between which the tacky member is to be interposed.

In the optical laminate, before laminating the second member to the first member, a tacky member may be disposed on a surface on the side opposite the side facing the first member of the second member. At an appropriate stage after the second member is laminated to the first member, a tacky member may be disposed on a surface on the side opposite the side facing the first member of the second member. In the optical laminate, a separator is laminated to the tacky member disposed on a surface on the side opposite the side facing the first member of the second member, before or after the tacky member is disposed on the surface of the second member.

The flexible image display device may be fabricated by producing an optical laminate beforehand, and, after removing the member 3B (specifically, the separator) from the optical laminate, attaching the exposed tacky member to the member 3A. The image display device may be fabricated by laminating the member 3A and the second member to each other, with a tacky member interposed therebetween, then, laminating the first member to the second member with a tacky member interposed therebetween, and subsequently, laminating the window member to the first member with a tacky member interposed therebetween. A laminate of the member 3A and the second member and a laminate of the window member and the first member may be prepared beforehand, and these laminates may be laminated to each other, with a tacky member interposed between the first member and the second member.

These fabrication methods are merely illustrative examples, and the present invention is not limited thereto. When the flexible image display device or the optical laminate includes the touch sensor-equipped panel member, it can be fabricated by laminating the members in a manner similar to these fabrication methods.

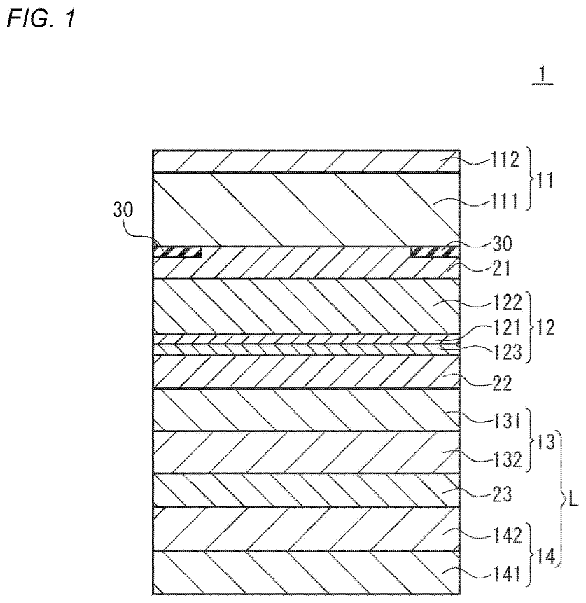

FIG. 1 is a schematic cross-sectional view of a flexible image display device of a first embodiment according to the above aspect of the present invention. A flexible image display device 1 includes a laminate of: a window member 11; an optical film 12, serving as the first member; a touch sensor 13, serving as the second member; and a panel member 14 serving as the member 3A. A laminate of the touch sensor 13 serving as the second member and the panel member 14 serving as the member 3A corresponds to a first laminate L. The optical film 12 and the window member 11 are laminated to each other, with a tacky member 21 interposed between the optical film 12 and the window member 11. The touch sensor 13 is laminated to the window member 11, via the optical film 12. A tacky member 22 is interposed between the optical film 12 and the touch sensor 13. The panel member 14 is laminated to the window member 11 via the optical film 12 and the touch sensor 13. A tacky member 23 is interposed between the touch sensor 13 and the panel member 14. A laminate of the configuration excluding the panel member 14 in FIG. 1 and a separator (not shown) corresponds to the optical laminate.

The window member 11 includes, for example, a window film 111 and a hard coat layer 112 laminated to the window film 111. The hard coat layer 112 is provided on the side opposite the side facing the first member (the optical film 12) (specifically, on a surface on the side opposite the side facing the first member of the window film 111) in the window member 11. The value obtained by multiplying the elastic modulus E0 by the thickness T0 of the window member 11 satisfies E0×T0≤0.32.

The optical film 12 includes a polarizing plate constituted of a polarizer 121 and a protective film 122, and a retardation layer 123. The retardation layer 123 is disposed on the side facing the touch sensor 13 serving as the second member, and laminated to the polarizing plate on the polarizer 121 side.

The touch sensor 13 includes a transparent conductive layer 131, and a transparent film (touch sensor film) 132 serving as the transparent base material. The touch sensor 13 is disposed such that the transparent conductive layer 131 is in contact with the tacky member 22 disposed between the optical film 12 and the touch sensor 13.

The panel member 14 includes an organic EL panel (organic EL display) 141 and a thin-film sealing layer 142. The panel member 14 is disposed such that the thin-film sealing layer 142 is in contact with the tacky member 23 disposed between the touch sensor 13 and the panel member 14.

In the flexible image display device 1 and the optical laminate, E0×T0≤0.32 is satisfied, and the thickness of each of the layers of the tacky members 21 to 23 is controlled to be in the aforementioned range. This can ensure a high pencil hardness at the surface on the window member 11 side of the flexible image display device 1 and the optical laminate.

In FIG. 1, a frame-shaped decoration layer 30 is provided on a surface on the first member (optical film 12) side of the window member 11. In this case, by setting the thickness of the tacky member 21 to be in contact with the decoration layer 30 to 10 μm or more, the level difference due to the decoration layer 30 can be effectively absorbed.

Although FIG. 1 illustrates a case where the decoration layer 30 is formed on the surface on the first member (optical film 12) side of the window member 11, this should not be taken as limitation. The decoration layer 30 may be provided on a surface on the touch sensor 13 side of the optical film 12. In this case, by setting the thickness of the tacky member 22 to be in contact with the decoration layer 30 to 10 μm or more, the level difference due to the decoration layer 30 can be effectively absorbed.

FIG. 1 illustrates a case where the first member is the optical film 12, the second member is the touch sensor 13, and the member 3A is the panel member. Without limited thereto, a touch sensor may be laminated as the first member to the window member 11, and an optical film may be laminated as the second member to the window member 11 via the touch sensor. A laminate including the panel member as above may be used as the member 3A.

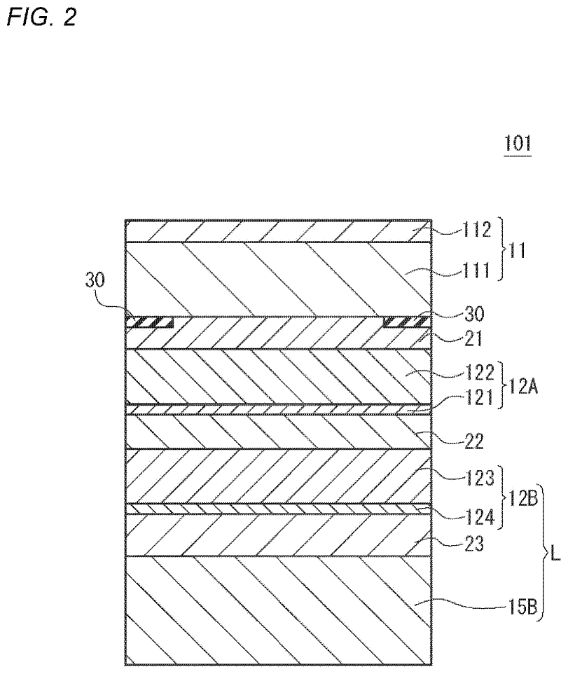

FIG. 2 is a schematic cross-sectional view of a flexible image display device of a second embodiment. A flexible image display device 101 includes a laminate of: the window member 11; an optical film 12A, serving as the first member; and the first laminate L. The first laminate L has a structure in which an optical film 12B serving as the second member and a second touch-sensor-equipped panel member 15B serving as the member 3A are laminated to each other. The tacky member 21 is interposed between the window member 11 and the optical film 12A. The tacky member 22 is interposed between the optical film 12A and the first laminate L, and the tacky member 23 is interposed between the optical film 12B and the second touch-sensor-equipped panel member 15B. The configuration other than the optical film 12A serving as the first member and the first laminate L is the same as that of the first embodiment, and for details thereof, the description of the first embodiment can be referred to.

The optical film 12A is a polarizing plate constituted of a polarizer 121 and a protective film 122. In the optical film 12A, the polarizer 121 is disposed on the side facing the tacky member 22 (in other words, on the side opposite to the window member 11). The optical film 12B is a laminate of two retardation layers 123 and 124.

With respect to the second embodiment, for example, a laminate of the configuration excluding the second touch-sensor-equipped panel member 15B, and a separator (second separator) (not shown) corresponds to the optical laminate.

In the second embodiment, E0×T0≤0.32 is satisfied, and the thickness of each of the layers of the tacky members 21 to 23 is controlled to be in the aforementioned range. This can ensure a high pencil hardness at the surface on the window member 11 side of the flexible image display device 101 and the optical laminate.

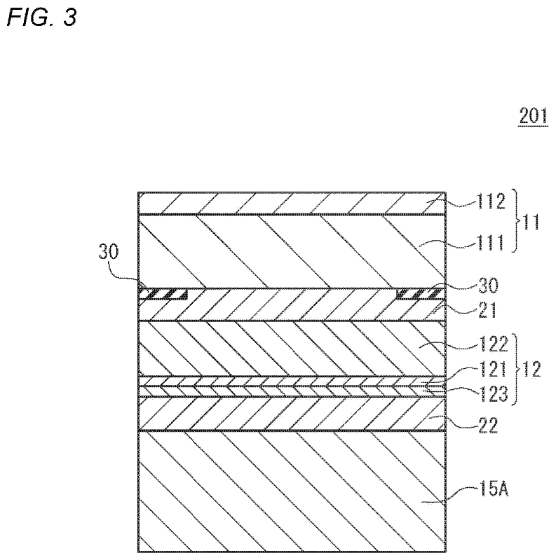

FIG. 3 is a schematic cross-sectional view of a flexible image display device according to a third embodiment. A flexible image display device 201 includes a laminate of: the window member 11; the optical film 12, serving as the first member; and a first touch-sensor-equipped panel member 15A. The tacky member 21 is interposed between the window member 11 and the optical film 12. The tacky member 22 is interposed between the optical film 12 and the first touch-sensor-equipped panel member 15A. The configuration is the same as that of the first embodiment, except that the first laminate L is replaced with the first touch-sensor-equipped panel member 15A. For the configuration other than the first touch-sensor-equipped panel member 15A, the description of the first embodiment can be referred to.

With respect to the third embodiment, a laminate of the configuration excluding the first touch-sensor-equipped panel member 15A, and a separator (first separator) (not shown) corresponds to the optical laminate.

In the third embodiment, E0×T0≤0.32 is satisfied, and the thickness of each of the layers of the tacky members 21 and 22 is controlled to be in the aforementioned range. This can ensure a high pencil hardness at the surface on the window member 11 side of the flexible image display device 201 and the optical laminate.

### EXAMPLES

The present invention will be specifically described below with reference to Examples and Comparative Examples. The present invention, however, is not limited to the following Examples.

### Examples 1 to 5 and Comparative Examples 1 to 9

### (1) Preparation of Evaluation Sample

Samples for evaluating the flexible image display device 1 as illustrated in FIG. 1 were prepared in the following procedure.

(a) Production of Window Member 11

The window member 11 produced here was a transparent polyimide film (product name “A_50_O”, manufactured by KOLON Inc., thickness: 50 μm) serving as the window film 111, with an acrylic hard coat layer serving as the hard coat layer 112 (thickness: 10 μm) disposed on one side thereof. The hard coat layer 112 was formed using a coating agent for hard coat layers. Specifically, first, the coating agent was applied to one side of the transparent polyimide film to form a coated layer, and the coated layer was heated together with the transparent polyimide film at 90° C. for 2 minutes. Then, using a high-pressure mercury lamp, the coated layer was irradiated with ultraviolet light at an accumulated light amount of 300 mJ/cm², into the hard coat layer 112. In this way, the window member 11 was produced. The elastic modulus of the window member as determined in the manner as described above was 4.7 GPa, and E0×T0 (=0.06 mm)=0.28.

The coating agent for hard coat layers was prepared by mixing 100 parts by mass of a multifunctional acrylate (product name “Z-850-16” manufactured by AICA Kogyo Co., Ltd.) serving as a base resin, 5 parts by mass of a leveling agent (trade name: GRANDIC PC-4100, manufactured by DIC Corporation), and 3 parts by mass of a photo-polymerization initiator (trade name: Irgacure 907, manufactured by Ciba Japan KK), and diluting the mixture with methyl isobutyl ketone to a dry solids concentration of 50 mass %.

For Comparative Example 9, a sample composed of the window member 11 only was prepared.

(b) Formation of Decoration Layer

A frame-shaped black ink layer (width: 15 mm, thickness: 5 μm) serving as the decoration layer 30 was provided by screen printing on a surface to be faced to the optical film 12 of the window member 11. The black ink used here was INQ-HF979 manufactured by Teikoku Printing Inks Mfg. Co., Ltd.

(c) Production of Optical Film 12

An optical film 12 was produced in the following procedure.

(Production of Polarizer 121)

An amorphous polyethylene terephthalate film (thickness: 100 μm) containing 7 mol % of isophthalic acid units was prepared as a base material made of a thermoplastic resin, and corona discharge treatment was performed on the surface of the film with an output discharge amount of 58 W/m²·min.

A polyvinyl alcohol (degree of polymerization: 4200, saponification degree: 99.2%) to which 1 mass % of an acetoacetyl-modified polyvinyl alcohol (trade name: GOHSEFIMER Z200 (average degree of polymerization: 1200, saponification degree: 98.5 mol %, acetoacetylation degree: 5 mol %, manufactured by The Nippon Synthetic Chemical Industry Co., Ltd.)) had been added was provided, and an aqueous coating liquid containing 5.5 mass % of the thus provided polyvinyl alcohol (PVA)-based resin was provided.

The coating liquid was applied onto the surface of the base material so as to provide a film thickness after drying of 12 and the whole was dried for 10 minutes by hot-air drying under an atmosphere of 60° C., thereby producing a laminate in which a layer of the PVA-based resin had been provided on the base material.

The obtained laminate was first stretched 1.8 times by free end stretching in the air (auxiliary stretching in air) at 130° C., to form a stretched laminate. Next, the stretched laminate was immersed in an insolubilizing aqueous boric acid solution having a solution temperature of 30° C. for 30 seconds, thereby performing a step of insolubilizing the PVA layer in which the PVA molecules contained in the stretched laminate had been oriented. The insolubilizing aqueous boric acid solution in this step is an aqueous boric acid solution having a boric acid content of 3 parts by mass per 100 parts by mass of water. The stretched laminate was dyed to form a colored laminate. The colored laminate was obtained by immersing the stretched laminate in a dyeing solution containing iodine and potassium iodide and having a solution temperature of 30° C. for a predetermined time such that the PVA layer constituting a finally produced polarizer had a single transmittance of 40 to 44%, thereby allowing the PVA layer included in the stretched laminate to be dyed with iodine. In this step, the dyeing solution is an aqueous solution containing iodine and potassium iodide (iodine concentration: 0.1 to 0.4 mass %, potassium iodide concentration: 0.7 to 2.8 mass %, ratio of iodine concentration to potassium iodide concentration: 1:7). Next, the colored laminate was immersed in a crosslinking aqueous boric acid solution at 30° C. for 60 seconds, thereby performing a step of allowing the PVA molecules of the PVA layer having iodine adsorbed thereto to be crosslinked with one another. The crosslinking aqueous boric acid solution in this step is an aqueous solution containing boric acid and potassium iodide (boric acid content: 3 parts by mass per 100 parts by mass of water, potassium iodide content: 3 parts by mass per 100 parts by mass of water).

The obtained colored laminate was stretched (in-boric-acid-solution stretching) 3.05 times in an aqueous boric acid solution at a stretching temperature of 70° C. in the same direction as in the above-described stretching in the air, thereby obtaining a laminate with a final stretching ratio of 5.50 times. The obtained laminate was taken out from the aqueous boric acid solution, and the boric acid attached to the surface of the PVA layer was washed with an aqueous potassium iodide solution (potassium iodide content: 4 parts by mass per 100 parts by mass of water). The washed laminate was dried by a drying step using a warm air of 60° C. The thickness of the polarizer 121 included in the dried laminate was 5

(Formation of Protective Film 122)

As the protective film 122, an acrylic film obtained by molding pellets of a methacrylic resin having a glutarimide ring unit into a film form by extrusion molding, followed by stretching, was used. The thickness of the protective film was 40 The protective film 122 and the polarizer 121 were bonded together using an adhesive (active energy ray-curable adhesive), and the adhesive was cured by being irradiated with ultraviolet light under the following conditions, thereby producing a polarizing plate.

Gallium-doped metal halide lamp: trade name “Light HAMMER10”, manufactured by Fusion UV Systems. Inc.

Valve: V valve

Peak illuminance: 1600 mW/cm²

Accumulated dose: 1000 mJ/cm² (wavelength: 380 to 440 nm)

The adhesive was prepared by mixing the following components such that their respective contents in 100 mass % of the adhesive had the following values, and stirring the mixture at 50° C. for one hour.

| | |
|---|---|
| Hydroxyethyl acrylamide | 11.4 mass % |
| Tripropylene glycol diacrylate | 57.1 mass % |
| Acryloylmorpholine | 11.4 mass % |
| 2-Acetoacetoxyethyl methacrylate | 4.6 mass % |
| Acrylic polymer (ARUFON UP-1190, | 11.4 mass % |
| manufactured by Toagosei Co., Ltd.) | |
| 2-Methyl-1-(4-methylthiophenyl)-2- | 2.8 mass % |
| morpholino propane-1-one | |
| Diethylthioxanthone | 1.3 mass % |

(Production of Retardation Layer 123)

As the retardation layer 123, a retardation film including two layers, namely, a quarter-wave-plate retardation layer and a half-wave-plate retardation layer in which a liquid crystal material had been oriented and immobilized. As the material for forming the half-wave-plate retardation layer and the quarter-wave-plate retardation layer, a polymerizable liquid crystal material (trade name: Paliocolor LC242, manufactured by BASF) exhibiting a nematic liquid crystalline phase was used. The retardation layer 123 was produced with reference to the description in paragraphs [0118] to [0120] of Japanese Laid-Open Patent Publication No. 2018-28573.

(Production of Optical Film 12)

The polarizing plate and the retardation layer 123 obtained as above were continuously bonded together by a roll-to-roll method, using the above-described adhesive (active energy ray-curable adhesive). At this time, the lamination was performed such that the axial angle between the slow axis and the absorption axis was 45°. Thus, an optical film 12 was produced. The elastic modulus E1 of the optical film as determined in the manner as described above was 4.8 GPa, and E1×T1 (=0.05 mm)=0.24.

(d) Preparation of Tackiness Agent

Tackiness agents (a1) to (a3) for forming tacky members 21 to 23 were prepared in the following procedure.

(a1) Acrylic Tackiness Agent 1: Acrylic Tackiness Agent Composition Obtained by Following the Procedure Below

(Preparation of Acrylic Polymer Solution)

A monomer mixture containing 94.9 parts by mass of butyl acrylate, 5 parts by mass of acrylic acid, and 0.1 parts by mass of 2-hydroxyethyl acrylate was charged into a four-necked flask equipped with a stirrer blade, a thermometer, a nitrogen inlet pipe, and a cooler. To 100 parts by mass of the monomer mixture, 0.1 parts by mass of 2,2′-azobisisobutyronitrile was added as a polymerization initiator, together with ethyl acetate. Nitrogen gas was introduced while the mixture to be obtained was stirred gently, to purge the flask with nitrogen. Next, with the liquid temperature in the flask kept around 55° C., the polymerization was allowed to proceed for 7 hours. To the resultant reaction liquid, ethyl acetate was added, to adjust the concentration of the polymer components therein to 30 mass %, and thus, a solution of an acrylic polymer A1 having a weight-average molecular weight of 2 million was prepared.

(Preparation of Acrylic Tackiness Agent 1)

To 100 parts by mass of the polymer components in the solution of the acrylic polymer A1, 0.6 parts by mass of an isocyanate-based crosslinking agent (trade name: CORONATE L, trimethylolpropane-tolylene diisocyanate, manufactured by Nippon Polyurethane Industry Co., Ltd.), and 0.08 parts by mass of a silane coupling agent (trade name KBM403, manufactured by Shin-Etsu Chemical Co., Ltd.) were added and mixed, to prepare an acrylic tackiness agent 1.

(a2) Acrylic Tackiness Agent 2: Acrylic Tackiness Agent Composition Obtained by Following the Procedure Below

(Preparation of Acrylic Oligomer)

First, 60 parts by mass of dicyclopentanyl methacrylate and 40 parts by mass of methyl methacrylate as monomer components, 3.5 parts by mass of α-thioglycerol as a chain transfer agent, and 100 parts by mass of toluene as a polymerization solvent were mixed, and the mixture was stirred under a nitrogen atmosphere at 70° C. for one hour. Next, 0.2 parts by mass of 2,2′-azobisisobutyronitrile as a thermal polymerization initiator was added. After reacting the mixture for 2 hours at 70° C., the temperature was elevated to 80° C., and the mixture was reacted for 2 hours. Thereafter, the reaction liquid was heated to 130° C. to remove the toluene, the chain transfer agent, and the unreacted monomers by drying, thereby obtaining a solid acrylic oligomer. The acrylic oligomer had a weight-average molecular weight of 5100, and a glass transition temperature (Tg) of 130° C.

(Preparation of Prepolymer Composition)

First, 43 parts by mass of lauryl acrylate, 44 parts by mass of 2-ethylhexyl acrylate, 6 parts by mass of 4-hydroxybutyl acrylate, and 7 parts by mass of N-vinyl-2-pyrrolidone, as well as 0.015 parts by mass of “Irgacure 184” manufactured by BASF as a photo-polymerization initiator were mixed, and the mixture was irradiated with ultraviolet light to perform polymerization, thereby obtaining a prepolymer composition (polymerization rate: about 10%).

(Preparation of Acrylic Tackiness Agent 2)

To 100 parts by mass of the above-described prepolymer composition, 0.07 parts by mass of 1,6-hexanediol diacrylate, 1 part by mass of the above-described acrylic oligomer, and 0.3 parts by mass of a silane coupling agent (“KBM403J” manufactured by Shin-Etsu Chemical Co., Ltd.) were added, and uniformly mixed, thereby preparing an acrylic tackiness agent 2.

(a3) Acrylic Tackiness Agent 3: Acrylic Tackiness Agent Composition Obtained by Following the Procedure Below

(Preparation of Acrylic Polymer Solution)

A monomer mixture containing 99 parts by mass of butyl acrylate and 1 part by mass of 4-hydroxybutyl acrylate was charged into a four-necked flask equipped with a stirrer blade, a thermometer, a nitrogen inlet pipe, and a cooler. To 100 parts by mass of the monomer mixture, 0.1 parts by mass of 2,2′-azobisisobutyronitrile was added as a polymerization initiator, together with ethyl acetate. Nitrogen gas was introduced while the mixture to be obtained was stirred gently, to purge the flask with nitrogen. Next, with the liquid temperature in the flask kept around 55° C., the polymerization was allowed to proceed for 7 hours. To the resultant reaction liquid, ethyl acetate was added, to adjust the concentration of the polymer components therein adjusted to 30 mass %, and thus, a solution of an acrylic polymer A2 having a weight-average molecular weight of 1.6 million was prepared.

(Preparation of Acrylic Tackiness Agent 3)

To 100 parts by mass of the polymer components in the solution of the acrylic polymer A2, 0.1 parts by mass of an isocyanate-based crosslinking agent (trade name: Takenate D110N, trimethylolpropane-xylylene diisocyanate, manufactured by Mitsui Chemicals, Inc.), 0.3 parts by mass of a peroxide-based crosslinking agent (benzoyl peroxide (trade name: Niper BMT, manufactured by Nippon Oil & Fats Co., Ltd.), and 0.08 parts by mass of a silane coupling agent (trade name KBM403, manufactured by Shin-Etsu Chemical Co., Ltd.) were added and mixed, to prepare an acrylic tackiness agent 3.

(e) Formation of Tackiness Agent Layer

Using the tackiness agents prepared in (d) above (tackiness agents shown in Table 1), a tackiness agent layer for forming each of the layers of tacky members 21 to 23 was formed. More specifically, the tackiness agents shown in Table 1 were each uniformly applied to a release film using a fountain coater, and was dried for 2 minutes in an air circulated thermostatic oven at 155° C., to form a tackiness agent layer on the surface of the release film. As the release film, a 38 μm-thick polyethylene terephthalate film (transparent base material, separator) that had been treated with a silicone-containing release agent was used. The thickness of the tackiness agent layer was adjusted by adjusting the application amount of the tackiness agent such that the thickness of the tacky member in each sample became as shown in Table 1.

(f) Fabrication of Laminate

Each of the members produced above was cut in a predetermined size, as necessary. The tackiness agent layer was transferred from the release film to one of the members between which the tacky member is to be sandwiched, and the members were laminated so as to sandwich the tackiness agent layer therebetween, and were pressure-bonded together using a hand roller. Evaluation samples were thus prepared in which the members were laminated via the tacky member. Here, a transparent polyimide film (product name “A_50_O”, manufactured by KOLON company, thickness: 50 μm) was used as a dummy for the touch sensor 13 and the panel member 14. The elastic modulus E2 (or E3) of the transparent polyimide film as determined in the manner as above was 6 GPa, and E2 (or E3)×T2 (or T3)=0.3.

### (2) Evaluation

(a) Storage Elastic Modulus of Tacky Member

The storage elastic modulus of each tacky member was determined in the following procedure. The storage elastic modulus of the tacky member produced using each of the acrylic tacky adhesive was as follows.

Tacky member produced using acrylic tackiness agent 1 (a1): 0.12 MPa

Tacky member produced using acrylic tackiness agent 2 (a2): 0.03 MPa

Tacky member produced using acrylic tackiness agent 3 (a3): 0.08 MPa

(b) Pencil Hardness Test

The evaluation samples were each placed on a glass plate, and the pencil hardness of the surface on the window member 11 side (the surface of the hard coat layer 112) was measured.

With respect to Comparative Example 9, a sample composed of the window member 11 only was used, to measure the pencil hardness of the surface of the hard coat layer 112.

(c) Decoration Formability

The evaluation samples were each observed from the surface side of the hard coat layer 112 with an optical microscope, for the conditions around the end of the decoration layer 30, to evaluate whether the level difference due to the decoration layer 30 was eliminated or not (decoration formability).

A: No air bubble was observed around the end of the decoration layer.

B: One or more air bubbles was observed around the end of the decoration layer.

(d) Adhesiveness (Bendability)

The evaluation samples obtained above were each cut into a 100 mm×20 mm strip shape, with the direction of the absorption axis of the polarizing plate coincided with the longitudinal direction of the strip. The sample thus cut out was set in a tension-free U-shape bier (“Small stand-alone endurance test machine DLMD111LHA” and “U-shape bending test jig” manufactured by Yuasa System Equipment Co., Ltd.), such that the window member side was to face inside when bent, to perform a bending test under the following conditions. The sample after the test was observed visually, to check the bent portion for the occurrence of delamination.

Environmental condition: 25° C., 55% RH

Test speed: 60 rpm

Bending radius: R3

Bending count: 100,000 times

Table 1 shows the results of Examples 1 to 5 and Comparative Examples 1 to 9. In Table 1, Examples 1 to 5 are denoted by E1 to E5, respectively, and Comparative Examples 1 to 9 are denoted by R1 to R9, respectively.

TABLE 1

| | | E1 | E2 | E3 | E4 | E5 | R1 | R2 | R3 | R4 | R5 | R6 | R7 | R8 | R9 |
|---|---|---|---|---|---|---|---|---|---|---|---|---|---|---|---|
| Tacky | Tackiness agent | a1 | a2 | a3 | a3 | a3 | a1 | a3 | a2 | a3 | a2 | a1 | a2 | a2 | — |
| member 21 | Thickness (μm) | 15 | 15 | 6 | 6 | 6 | 23 | 25 | 25 | 25 | 25 | 15 | 25 | 25 | — |
| Tacky | Tackiness agent | a1 | a2 | a3 | a1 | a3 | a1 | a3 | a2 | a3 | a3 | a1 | a1 | a3 | — |
| member 22 | Thickness (μm) | 15 | 15 | 6 | 15 | 18 | 23 | 25 | 25 | 25 | 6 | 15 | 15 | 6 | — |
| Tacky | Tackiness agent | a1 | a2 | a3 | a2 | a3 | a1 | a3 | a2 | a2 | a2 | a2 | a1 | a3 | — |
| member 23 | Thickness (μm) | 15 | 15 | 6 | 15 | 18 | 23 | 25 | 25 | 15 | 25 | 25 | 15 | 6 | — |

| | | | | | | | | | | | | | | |
|---|---|---|---|---|---|---|---|---|---|---|---|---|---|---|
| Pencil hardness | 2H | H | 4H | 2H | 2H | B | B | 6B | B | 3B | B | B | 5B | 4H |
| Decoration formability | A | A | B | B | B | A | A | A | A | A | A | A | A | — |

As shown in Table 1, in the case of the window member alone, a pencil hardness as high as 4H can be obtained at the surface of the hard coat layer side (R9). When the window member is laminated with other members with the tacky member interposed therebetween, however, there is a case where the pencil hardness at the surface on the window member side (specifically, the surface on the hard coat layer side) decreases considerably to B to 6B (R1 to R8). Despite this, by setting the thickness of all the three layers of tacky members to 18 μm or less, the decrease in the pencil hardness at the surface on the window member side can be suppressed, and a high pencil hardness can be ensured (E1 to E5). Such an effect can be hardly obtained even when the thickness of one or two of the three layers of tacky members is set to 18 μm or less (R4 to R8).

In view of the ease of absorbing the level difference due to the decoration layer, the thickness of the tacky member to be in contact with the decoration layer is preferably set to greater than 6 μm (specifically, to 10 μm or more).

In Examples 1 to 5 and Comparative Examples 1 to 8, no delamination was observed at the bent portion in the bending test, showing good adhesiveness.

### Examples 6 to 11 and Comparative Examples 10 to 16

Samples for evaluating the flexible image display device 201 as illustrated in FIG. 3 were prepared, so as to correspond to Examples 1 to 5. In place of the dummy for the touch sensor 13 and the panel member 14 used in Example 1, a transparent polyimide film (product name “A_50_O”, manufactured by KOLON Inc., thickness: 50 μm) was used as a dummy for the first touch-sensor-equipped panel member 15A.

The tackiness agent layer was formed using tackiness agents prepared in a manner similarly to those in Examples 1 to 5 (tackiness agents shown in Table 2). The thickness of the tackiness agent layer was adjusted by adjusting the application amount of the tackiness agent such that the thickness of the tacky member in each sample became as shown in Table 2.

Evaluation was made similarly to in Examples 1 to 5 using the obtained samples.

Table 2 shows the results of Examples 6 to 11 and Comparative Examples 10 to 16. In Table 2, Examples 6 to 11 are denoted by E6 to E11, respectively, and Comparative Examples 10 to 16 are denoted by R10 to R16, respectively. The result of Comparative Example 9 (R9) is also shown in Table 2.

TABLE 2

| | | E6 | E7 | E8 | E9 | E10 | R11 | R10 | R11 | R12 | R13 | R14 | R15 | R16 | R9 |
|---|---|---|---|---|---|---|---|---|---|---|---|---|---|---|---|
| Tacky | Tackiness agent | a1 | a2 | a3 | a3 | a3 | a3 | a1 | a3 | a2 | a1 | a2 | a3 | a2 | — |
| member 21 | Thickness (μm) | 15 | 15 | 6 | 6 | 6 | 6 | 23 | 25 | 25 | 15 | 25 | 5 | 25 | — |
| Tacky | Tackiness agent | a1 | a2 | a3 | a1 | a2 | a3 | a1 | a3 | a2 | a2 | a1 | a2 | a3 | — |
| member 22 | Thickness (μm) | 15 | 15 | 6 | 15 | 15 | 18 | 23 | 25 | 25 | 25 | 15 | 25 | 5 | — |

| | | | | | | | | | | | | | | |
|---|---|---|---|---|---|---|---|---|---|---|---|---|---|---|
| Pencil hairiness | 2H | H | 4H | 3H | 2H | 2H | HB | B | 6B | B | 2B | F | B | 4H |
| Decoration formability | A | A | B | B | B | B | A | A | A | A | A | B | A | — |

As shown in Table 2, in the case of the window member alone, a pencil hardness as high as 4H can be obtained at the surface of the hard coat layer side (R9). When the window member is laminated with other members with the tacky member interposed therebetween, however, the pencil hardness decreases considerably to F to 6B (R10 to R16). Despite this, in the sample of the flexible image display device according to the third embodiment, by setting the thickness of all the two layers of tacky members to 18 μm or less, a high pencil hardness can be ensured (E6 to E11).

In the case of the third embodiment, too, in view of the ease of absorbing the level difference due to the decoration layer, the thickness of the tacky member to be in contact with the decoration layer is preferably set to greater than 6 μm (specifically, to 10 μm or more).

In Examples 6 to 11 and Comparative Examples 10 to 16, no delamination was observed at the bent portion in the bending test, showing good adhesiveness.

### INDUSTRIAL APPLICABILITY

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### REFERENCE SIGNS LIST

1, 101, 201: Flexible image display device
11: Window member
111: Window film
112: Hard coat layer
12, 12A, 12B: Optical film
121: Polarizer
122: Protective film
123, 124: Retardation layer
13: Touch sensor
131: Transparent conductive layer
132: Transparent film
14: Panel member
141: Organic EL panel
142: Thin-film sealing layer
15A: First touch-sensor-equipped panel member
15B: Second touch-sensor-equipped panel member
L: First laminate
21, 22, 23: Tacky member
30: Decoration layer

1. A flexible image display device, comprising:
a window member;
a first member laminated to the window member;
a first laminate or a first touch-sensor-equipped panel member laminated to the window member via the first member; and
a plurality layers of tacky members, wherein
the first laminate is a laminate of a second member and a member 3A, the second member laminated via the first member to the window member, the member 3A laminated via the first member and the second member to the window member;
when the flexible image display device includes the first laminate,
one of the first member and the second member is an optical film, and the other is an optical film or a touch sensor,
the member 3A includes at least a panel member, and
the plurality layers of tacky members at least include three layers disposed respectively between the window member and the first member, between the first member and the second member, and between the second member and the member 3A;
when the flexible image display device includes the first touch-sensor-equipped panel member,
the first member is an optical film, and
the plurality layers of tacky members at least include two layers disposed respectively between the window member and the first member, and between the first member and the first touch-sensor-equipped panel member;
when the window member has a tensile elastic modulus (GPa) denoted by E0 and a thickness (mm) denoted by T0, E0×T0 regulates a pencil hardness of a surface on the window member side of the flexible image display device and satisfies E0×T0≤0.32, the pencil hardness being specified in JIS K 5600-5-4:1999; and
a thickness of each of the plurality layers of tacky members satisfies a condition of 18 μm or less.

2. The flexible image display device according to claim 1, including the member 3A, wherein
one of the first member and the second member is the optical film, and the other is the touch sensor.

3. The flexible image display device according to claim 1, wherein
the plurality layers of tacky members further include at least one layer disposed within the member 3A.

4. The flexible image display device according to claim 1, wherein
the member 3A includes a second touch-sensor-equipped panel member, and
each of the first member and the second member is the optical film.

5. The flexible image display device according to claim 1, wherein a decoration layer is provided between the window member and the touch sensor or the first touch-sensor-equipped panel member, so as to be in contact with one of the plurality layers of tacky members.

6. The flexible image display device according to claim 4, wherein a decoration layer is provided between the window member and the second touch-sensor-equipped panel member, so as to be in contact with one of the plurality layers of tacky members.

7. The flexible image display device according to claim 5, wherein a thickness of the tacky member to be in contact with the decoration layer is 10 μm or more.

8. The flexible image display device according to claim 1, wherein the thickness of each of the plurality layers of tacky members satisfies a condition of 3 μm or more.

9. The flexible image display device according to claim 1, having a hardness of higher than F on the window member side, the hardness measured by a pencil hardness test specified in JIS K 5600-5-4:1999.

10. The flexible image display device according to claim 1, wherein a storage modulus at 25° C. of each of the plurality layers of tacky members satisfies a condition of 1 MPa or less.

11. The flexible image display device according to claim 1, wherein
the window member includes a hard coat layer, and
the hard coat layer is provided at least on a side opposite a side facing the first member of the window member.

12. An optical laminate for use in the flexible image display device according to claim 1, the optical laminate comprising:
a window member;
a first member laminated to the window member;
a second laminate or a first separator laminated to the window member via the first member; and
a plurality layers of tacky members, wherein
the second laminate is a laminate of a second member and a member 3B, the second member laminated via the first member to the window member, the member 3B laminated via the first member and the second member to the window member;
when the optical laminate includes the second laminate,
one of the first member and the second member is an optical film, and the other is an optical film or a touch sensor,
the member 3B includes at least a second separator, and
the plurality layers of tacky members at least include three layers disposed respectively between the window member and the first member, between the first member and the second member, and between the second member and the member 3B;
when the optical laminate includes the first separator,
the first member is an optical film, and
the plurality layers of tacky members at least include two layers disposed respectively between the window member and the first member, and between the first member and the first separator;
when the window member has a tensile elastic modulus (GPa) denoted by E0 and a thickness (mm) denoted by T0, E0×T0 regulates a pencil hardness of a surface on the window member side of the flexible image display device and satisfies E0×T0≤0.32, the pencil hardness being specified in JIS K 5600-5-4:1999; and
a thickness of each of the plurality layers of tacky members satisfies a condition of 18 μm or less.

13. The optical laminate according to claim 12, including the member 3B, wherein
one of the first member and the second member is the optical film, and the other is the touch sensor.
